(19) United States
(12) Patent Application Publication
(10) Pub. No.: US 2026/0247547 A1
(43) Pub. Date: Aug. 20, 2026

(54) CONTROL BOX

(71) Applicant: AUTONICS CORPORATION, Busan (KR)

(72) Inventor: Yongmoon KIM, Incheon (KR)

(73) Assignee: AUTONICS CORPORATION, Busan (KR)

(21) Appl. No.: 19/327,617

(22) Filed: Sep. 12, 2025

(30) Foreign Application Priority Data
Feb. 17, 2025 (KR) 10-2025-0020172
Apr. 25, 2025 (KR) 10-2025-0054942

(51) Int. Cl. H05K 5/00; H05K 5/02

(52) U.S. Cl. CPC H05K 5/0069; H05K 5/0221

(57) ABSTRACT

The control box according to an embodiment of the present invention for achieving the above-mentioned purpose comprises: a housing; a circuit board located inside the housing; and a board holder including a first portion connected to the circuit board and a second portion connected to the housing; a fastening member for fixing the board holder to the housing, wherein at least one of the planes passing through the first part and the second part is parallel to a component mounting surface of the circuit board.

### CROSS-REFERENCE TO RELATED APPLICATIONS

The present application claims the benefits of priority to Korean Patent Application No. 10-2025-0020172, filed on Feb. 17, 2025, and 10-2025-0054942, filed on Apr. 25, 2025, whose entire disclosures are hereby incorporated by reference.

### The Background

### 1.the Field

The present invention relates to a control box in which a circuit board, etc. is mounted internally.

### 2. Description of the Related Art

One or more circuit boards are mounted inside the control box, and the one or more circuit boards are generally fixed to the interior of the housing constituting the control box by a plurality of fastening members.

Meanwhile, in a structure where multiple control boxes are arranged densely in a horizontal direction, in order to separate and replace the circuit boards inside the control boxes except for the control box located at the outermost edge, it is necessary to firstly go through a module separation process to separate the control boxes adjacent to the target control box. Then, after separating the side cover of the control box that contacts the side of the adjacent control box, it is necessary to finally separate the multiple fasteners that secure the circuit board. As a result, there is a problem that the labor and repair costs for replacing the circuit board increase.

### THE SUMMARY

The present invention is proposed to improve the above-mentioned problems.

The control box according to an embodiment of the present invention for achieving the above-mentioned purpose comprises: a housing; a circuit board located inside the housing; and a board holder including a first portion connected to the circuit board and a second portion connected to the housing; a fastening member for fixing the board holder to the housing, wherein at least one of the planes passing through the first part and the second part is parallel to a component mounting surface of the circuit board.

A front end of the circuit board has a holder engagement groove into which the first part engages, and the first part has an engagement bar that engages with the holder engagement groove.

A fastening boss is formed on the second part, a holder flange is formed on an inner side of the housing to accommodate the fastening boss, and the fastening boss is fixed to the holder flange by the fastening member.

The fastening member is sequentially inserted into the fastening boss and the holder flange in a direction from a front to a rear of the housing.

The board holder includes a cable holder protruding for cable support.

The board holder includes a flexible latch portion formed thereon, and the circuit board includes a protrusion insertion portion into which the latch portion is inserted.

The latch portion includes: a latch body formed by cutting a portion of the circuit board; and a latch protrusion protruding from an end of the latch body, wherein the latch protrusion is inserted into the protrusion insertion hole.

An end of the latch protrusion is formed at an oblique angle, such that during the process of attaching the board holder to the circuit board, the latch body gradually bends as it slides along a surface of the circuit board, and when the latch protrusion is inserted into the protrusion insertion hole, the latch body is restored to its original position by elastic force.

One or more insertion protrusions are formed on a rear end of the circuit board, and the housing includes a board support bracket that supports the one or more insertion protrusions.

One or more insertion holes are formed inside the board support bracket in which the one or more insertion protrusions are inserted.

After the circuit board is inserted into the housing until the one or more insertion protrusions are inserted into the one or more insertion holes, the one or more insertion protrusions are supported by being engaged with the board support bracket by a descending motion of the circuit board.

The bottom surface of the housing is formed with a pair of support ribs that support a lower end of the circuit board, and when the one or more insertion protrusions engage with the circuit board support bracket, the lower end of the circuit board is inserted into a space formed between the pair of support ribs.

One or more light-transmitting holes are formed inside the board holder, and a partition wall is formed between the multiple light-transmitting holes.

One or more light sources are mounted on the circuit board.

In a state where the board holder is coupled to the circuit board, light emitted from the one or more light sources is directed toward the one or more light-transmitting holes.

The control box of the present invention further comprises a cover that opens or closes an opened front surface of the housing, a light guide protrudes from a rear of the cover, and one or more light passages are formed inside the light guide.

The board holder is bent to cover a corner where the front and top edges of the circuit board meet.

The direction in which the circuit board is inserted into the housing and the direction in which the fastening member is inserted into the housing are the same.

A control box according to a present invention in another aspect, comprises: a housing; a circuit board located inside the housing; a board holder connected to the housing and the circuit board; and a fastening member for fixing the board holder to the housing, wherein at least a portion of an edge of the circuit board is inserted into the board holder, so that both sides of the circuit board are supported by the board holder.

A control box according to a present invention in a further another aspect, comprises: a housing; a circuit board located inside the housing; a board holder connected to the housing and the circuit board; and a fastening member for securing the board holder to the housing, wherein the board holder is secured to a protruding portion within the housing by the fastening member, thereby keeping the circuit board spaced apart from the inner wall of the housing.

The control box according to the embodiment of the present invention having the above configuration has the following effects.

First, to replace the circuit board inside the housing, it is only necessary to open the cover attached to the front of the housing and separate the board holder from the housing, so even when a plurality of control boxes are arranged densely in a lateral direction, there is no need to disassemble or separate adjacent control boxes.

Second, since fastening members such as screws do not need to directly penetrate the circuit board to secure it inside the housing, the risk of damaging the circuit board is minimized.

Third, since the insertion direction of the fastening members for combining the fastening bosses provided on the board holder with the holder brackets provided inside the housing is parallel to the insertion and removal direction of the circuit board, there is no need to separate the side of the housing to separate the circuit board, thereby improving work efficiency.

Fourth, since the board holder is equipped with a cable holder, there is no need for a separate means to organize cables connected to the circuit board.

Fifth, since the front and top of the circuit board are supported by the board holder, the rear of the circuit board is supported by the board support bracket, and the bottom of the circuit board is supported by the board support rib, even if vibration is transmitted to the control box from the outside, the circuit board is stably fixed inside the housing without shaking.

Sixth, since only one fastening member is used to fix the circuit board, there is an effect of reducing labor and costs.

### BRIEF DESCRIPTION OF THE DRAWINGS

FIG. 1 is a front perspective view of the control box according to an embodiment of the present invention.

FIG. 2 is an exploded perspective view of the control box.

FIG. 3 is a perspective view of the control box showing the circuit board fixed inside the housing by the board holder.

FIG. 4 is a sectional perspective view of the control box cut along 4-4 in FIG. 3.

FIG. 5 is a perspective view of the board holder viewed from one side.

FIG. 6 is a perspective view of the board holder viewed from the other side.

FIG. 7 is a sectional perspective view of the board holder cut along 7-7 in FIG. 5.

FIG. 8 is a perspective view of the circuit board mounted in the control box according to an embodiment of the present invention.

FIG. 9 is an assembly drawing showing the process of attaching the board holder to the circuit board in sequence.

FIG. 10 is a cross-sectional view of the housing cut along line 4-4 in FIG. 3 with the circuit board separated.

FIG. 11 is a cross-sectional view of the housing cut along line 11-11 in FIG. 10 with the circuit board attached to the housing.

FIG. 12 is a front perspective view of the cover attached to the housing.

FIG. 13 is a rear perspective view of the cover.

FIG. 14 is a rear perspective view of the slider that constitutes the cover lock module according to an embodiment of the present invention.

FIG. 15 is a front perspective view of the upper locker that constitutes the cover lock module according to an embodiment of the present invention.

FIG. 16 is a rear perspective view of the upper locker.

FIG. 17 is a perspective view of the side locker constituting the cover lock module according to an embodiment of the present invention.

FIG. 18 is an enlarged view showing the step portion of the cover on which the cover lock module according to an embodiment of the present invention is mounted.

FIG. 19 is a cross-sectional view of the control box along the 19-19 line in FIG. 12, showing the appearance before the slider descends.

FIG. 20 is a rear view of the cover in the state shown in FIG. 19.

FIG. 21 is a cross-sectional view of the control box along the 19-19 line in FIG. 12, showing the state where the slider has descended to its maximum extent.

FIG. 22 is a rear view of the cover in the state shown in FIG. 21.

FIG. 23 is a diagram showing the path of light emitted from the light source.

### DETAILED DESCRIPTION

The following is a detailed description of the control box according to an embodiment of the present invention with reference to the drawings.

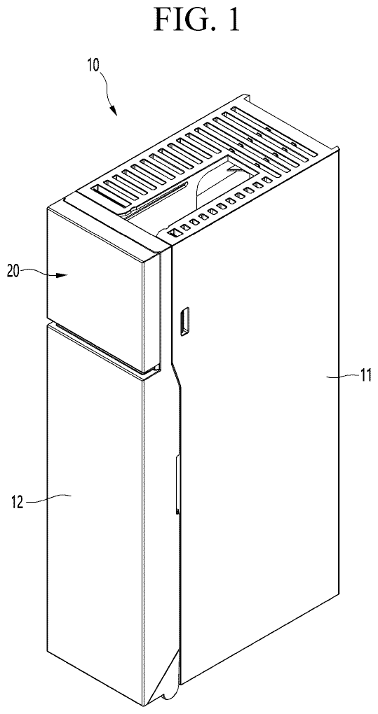

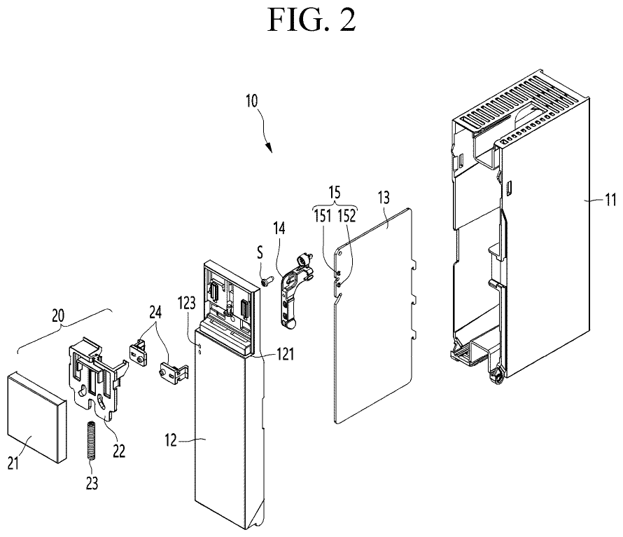

FIG. 1 is a front perspective view of the control box according to an embodiment of the present invention, and FIG. 2 is an exploded perspective view of the control box.

Referring to FIGS. 1 and 2, the control box 10 according to an embodiment of the present invention includes a housing 11, a cover 12 coupled to a front of the housing 11, a circuit board 13 mounted inside the housing 11, a board holder 14 for fixing the circuit board 13 inside the housing 11, and a fastening member S for fixing the board holder 14 to the housing 11.

In detail, the control box 10 may further include a cover lock module 20 provided on the cover 12. The cover lock module 20 is defined as a locking means for allowing the cover 12 to be coupled to or separated from the housing 11.

The cover lock module 20 includes a slider 21 placed on a step portion 121 provided on a front of the cover 12, an upper locker 22 that penetrates the step portion 121 and is coupled to the cover 12, a spring 23 coupled vertically to the upper locker 22, and a pair of side lockers 24 that are inserted through the step portion 121.

The step portion 121 has a plurality of holes into which a portion of the upper locker 22 and the side lockers 24 are inserted, and the slider 21 covers a front surface of the upper locker 22 to block external exposure. Furthermore, the vertical length of the slider 21 is formed to be shorter than the vertical length of the step portion 121, and the slider 21 is slidably coupled to the step portion 121.

Furthermore, when the slider 21 slides to move, the upper locker 22 also slides together with the slider 21. Specifically, when the user lowers the slider 21, the upper locker 22 also descends, the spring 23 is compressed, and simultaneously, the side locker 24 moves horizontally towards a center of the step portion 121. As a result, the cover 21 becomes separable from the housing 11, i.e., in an openable state, and by rotating the cover 21, one end of the cover 21 is separated from the housing 11.

On the other hand, when the force acting on the slider 21 is removed, the slider 21 and the upper locker 22 rise to their original positions due to the restoring force of the spring 23, the side locker 24 moves horizontally toward the left and right edges of the step portion 121, causing the cover 21 to remain engaged with the housing 11, i.e., in a closed state.

The configuration and operation of the cover lock module 20 will be described in more detail below with reference to the drawings.

Meanwhile, the circuit board 13 may be equipped with a light source 15, and a portion of the cover 12 corresponding to a front of the light source 15 may be formed thinner than other portions to form a so-called hidden display 123. Therefore, when the light source 15 is off, the hidden display is not visible to the user, but when the light source 15 is turned on, the light emitted from the light source 15 passes through the hidden display 123 formed on the cover 12 and becomes visible to the user.

Alternatively, a portion of the cover where the light emitted from the light source 15 strikes can be formed to be transparent or translucent.

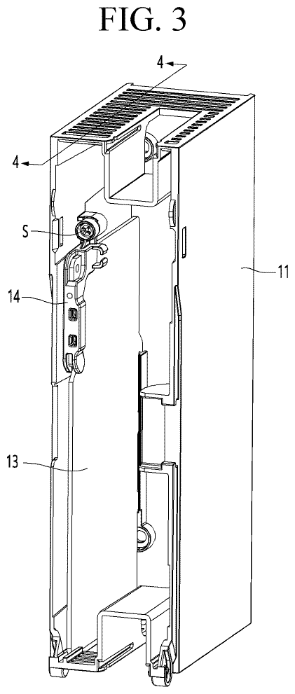

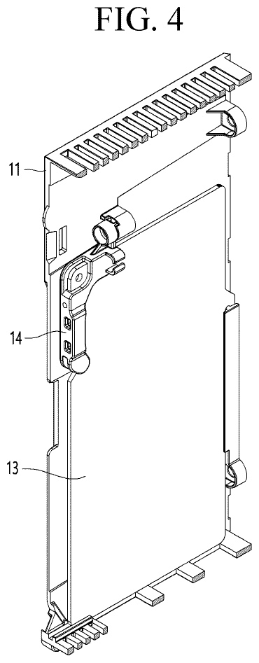

FIG. 3 is a perspective view of a control box showing the circuit board fixed inside the housing by the board holder, and FIG. 4 is a sectional perspective view of the control box cut along 4-4 in FIG. 3.

Referring to FIGS. 3 and 4, the board holder 14 is inserted into a corner of the circuit board 13. Specifically, a part of the board holder 14 is hooked onto the circuit board 13, and the other part is fixed to the housing 11, thereby preventing the circuit board 13 from shaking in the width direction of the housing 11 inside the housing 11. For example, a part of the board holder 14 may be defined as a first part, and the other part may be defined as a second part. More specifically, the first part may be defined as one end of the board holder 14, and the second part may be defined as the other end of the board holder 14.

Furthermore, since a surface passing by the circuit board 13 and one of a plurality of surfaces passing by the first and second portions of the board holder 14 is parallel to each other, the circuit board 13 and the board holder 14 have the advantage of being mountable in a configuration where they are positioned close to one side of the interior of the housing 11. The surface passing by the circuit board 13 may be understood as a surface splitting a thickness of the circuit board 13 into two.

In other words, due to the structure and combination form of the board holder 14, while side surfaces of the circuit board 13 and the housing 11 are maintained in a parallel state, the circuit board 13 can be mounted in a position very close to the inner side surface of the housing 11.

The board holder 14 can be inserted into one corner of the circuit board 13, for example, the corner where the front and top surfaces meet, and the board holder 14 can be fixed to the housing 11 by the fastening member S.

As shown in the figure, the front and rear of the housing 11 are open, and heat dissipation slits (described later) are formed on the top and/or bottom surfaces, allowing heat generated by the circuit board 13 to be quickly released to the outside. The structure of the housing 11 will be described in more detail below with reference to the drawings.

First, the structure and function of the board holder 14 will be described in detail with reference to the drawings.

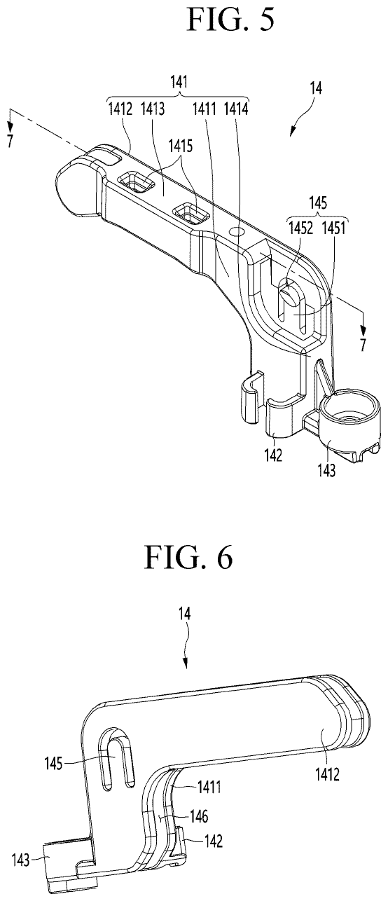

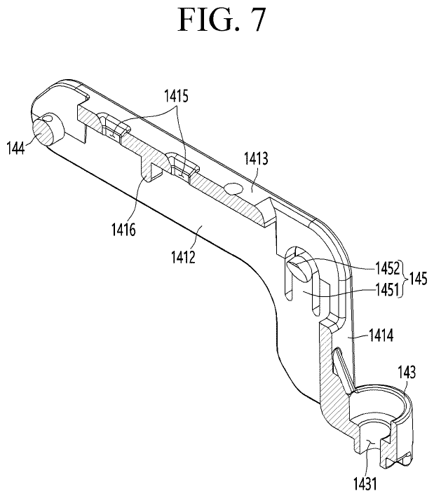

FIG. 5 is a perspective view of the board holder as seen from one side, FIG. 6 is a perspective view of the board holder as seen from the other side, and FIG. 7 is a sectional perspective view of the board holder along the line 7-7 in FIG. 5.

Referring to FIGS. 5 to 7, the board holder 14 constituting the control box 10 according to the embodiment of the present invention is formed in a roughly “¬” shape and can be mounted at the corner where the front end and an upper end of the circuit board 13 meet.

In detail, the board holder 14 includes a holder body 141, which may be formed in a “¬” shaped configuration with a single bend.

The holder body 141 includes a first surface 1411 covering one of the left and right sides of the circuit board 13, a second surface 1412 covering the other side, and a third surface 1413 connecting the front ends of the first surface 1411 and the second surface 1412 to cover a portion of the front end of the circuit board 13, and a fourth surface 1414 that covers the first surface 1411 and the second surface 1412 and covers a portion of the upper end of the circuit board 13. The surfaces of the holder body 141 corresponding to the opposite sides of the third surface 1413 and the fourth surface 1414 are open, and the circuit board 13 is inserted through the open portions.

From another perspective, the holder body 141 can be described as including a first body portion that covers the front end of the circuit board 13 and a second body portion that is bent from an upper end of the first body portion to cover the upper end of the circuit board 13. The first body portion may be formed longer than the second body portion, but this is not limited thereto. Furthermore, one end of the holder body 141, i.e., the end of the first body portion, is rotatably connected to the circuit board 13, and the other end of the holder body 141, i.e., the end of the second body portion, is fixed to the inner side surface of the housing 11.

Meanwhile, the board holder 14 may further include a cable holder 142 extending from the holder body 141. Specifically, the cable holder 142 is formed on the first surface 1411 and may be formed at the end of the second body portion. The cable holder 142 extends in a loop shape at a position facing each other, and can support a cable extending from a connector inserted into the circuit board 13. This allows efficient use of the internal space of the housing 11 without the need for separate means for cable management.

The board holder 14 may further include a fastening boss 143 extending from the holder body 141. The fastening boss 143 is formed on the fourth surface 1414 and may be formed at the end of the second body portion. A fastening hole 1431 is formed on the inner side of the fastening boss 143, and the fastening member penetrates the fastening hole 1431 in a direction parallel to the extension direction of the second body portion.

The board holder 14 may further include a latch bar 144 formed at the end of the first body portion. Specifically, the latch bar 144 is a cylindrical bar connecting the first surface 1411 and the second surface 1412. The latch bar 144 functions as a rotational axis of the board holder 14 when the board holder 14 is coupled to the circuit board 13. Here, the latch bar 144 may be formed on the first portion of the board holder 14, and the first portion may be understood as one end of the board holder 14. Furthermore, the fastening boss 143 may be formed on the second portion of the board holder 14, and the second portion may be understood as the other end of the board holder 14.

The board holder 14 may further include a latch portion 145 formed on the second surface 1412 constituting the second body portion. Specifically, the latch portion 145 may be formed by cutting a portion of the second surface 1412 in a reverse U-shape. The latch portion 145 includes a latch body 1451 extending to a predetermined length and a latch protrusion 1452 protruding toward the first surface 1411 from the end of the latch body 1451. The latch body 1451 has elasticity due to the reverse U-shaped cutout and can be bent. The end of the latch protrusion 1452 can be formed at an oblique angle.

The third surface 1413 of the board holder 14 may have one or more light-transmitting holes 1415, and in this embodiment, two light-transmitting holes are formed. When two or more light-transmitting holes are formed, a barrier wall 1416 extends from the rear side of the third surface 1413 corresponding to a position between the adjacent light-transmitting holes. The barrier wall 1416 prevents light from different light sources from interfering with each other before passing through the light-transmitting holes 1415.

The width (or thickness) of the third surface 1413 of the board holder 14 where the light-transmitting holes 1415 are formed may be larger than that of other parts.

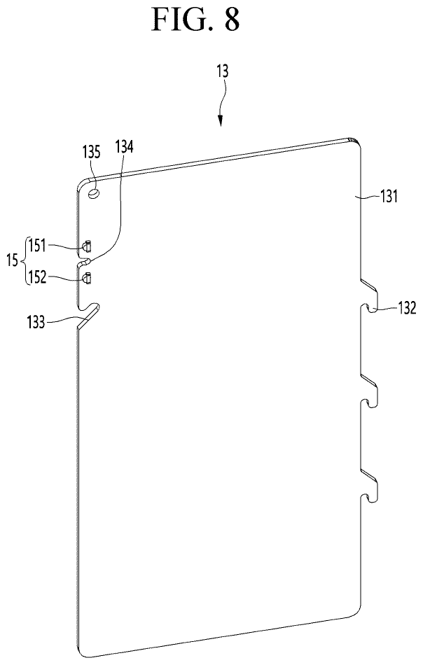

FIG. 8 is a perspective view of a circuit board mounted in a control box according to an embodiment of the present invention.

Referring to FIG. 8, the circuit board 13 according to the present invention includes a board body 131 formed in a rectangular shape, and the board body 131 may include a front end, a rear end, a top end, a bottom end, a left side, and a right side.

In detail, on one side of the board body 131, for example, on one side of the front end of the board body 131, a holder engagement groove 133 may be formed to be recessed. The holder engagement groove 133 may extend toward the upper end in a sloped manner as it moves toward the rear end of the board body 131.

The insertion of the latch bar 144 of the board holder 14 into the holder latch groove 133 is one embodiment for causing the first portion of the board holder 14 to latch onto the circuit board 13, and it should be noted that other forms of latching means may also be provided.

Specifically, an embodiment that the holder latch groove 133 is formed on the upper surface of the board body 131, and the latch bar 144 of the board holder 14 is formed on the second portion of the board holder 14, and the fastening boss 143 of the board holder 14 is formed on the first portion of the board holder 14 may be suggested.

Among the front ends of the board body 131, a barrier insertion groove 134 may be recessed at the point where the board body 131 is spaced apart from the holder latch groove 133 toward the upper end of the board body 131. The barrier wall 1416 formed on the third surface 1413 of the board holder 14 is inserted into the barrier wall insertion groove 134.

A light source 15 is mounted on one side of either the left side or the right side of the board body 131 The light source 15 may include a first light source 151 and a second light source 152 that are mounted on points opposite to each other with respect to the blocking wall insertion groove 134. There is no limit to the number of light sources mounted on the board body 131, and blocking walls and blocking wall insertion grooves into which the blocking walls are inserted may be formed between adjacent light sources to prevent light interference. The light emitted from the light source 15 is irradiated toward the front end of the board body 131 and sequentially passes through the light passage hole 1415 formed in the board holder 14 and the hidden display 123 provided in the cover 12.

A protrusion insertion portion 135 is formed at the corner where the front end and upper end of the board body 131 meet, and the latch protrusion 1452 constituting the latch portion 145 of the board holder 14 is connected to the protrusion insertion portion 135. For example, the protrusion insertion portion 135 is provided in the form of a hole, allowing the latch protrusion 1452 to be inserted into the protrusion insertion portion 135.

Furthermore, when the board holder 14 is coupled to the board body 131, the inclined end of the latch protrusion 1452 comes into contact with the other side of either the left side or the right side of the board body 131. Furthermore, during the process of the second body portion of the board holder 14 being coupled to the circuit board 13, the latch body 1451 of the latch portion 145 progressively bends outward from the board holder 14. Furthermore, when the latch protrusion 1452 is inserted into the protrusion insertion portion 135, the bent latch body 1451 returns to its original position.

As another example of the protrusion insertion portion 135, it may be provided in a hook shape so that the latch protrusion 1452 can be hooked onto the protrusion insertion portion 135.

Meanwhile, the circuit board 13 includes one or more insertion protrusions 132 that protrude from the rear end of the board body 131. In detail, the one or more insertion protrusions 132 may extend obliquely from the rear end of the board body 131 and then bend downward toward the lower end.

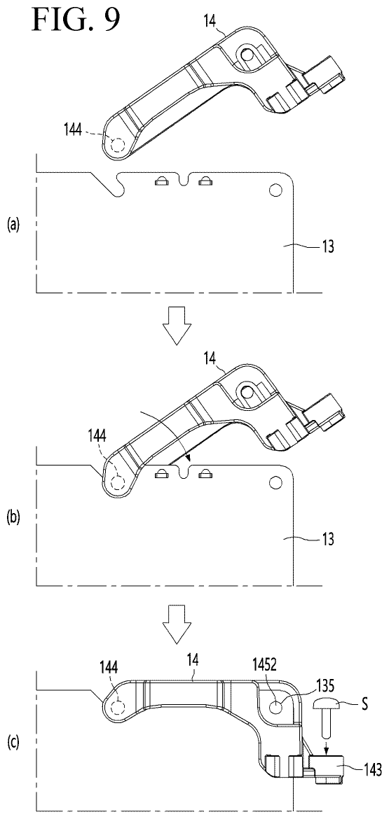

FIG. 9 is an assembly drawing showing the process of attaching the board holder to the circuit board in sequence.

Referring to (a) to (c) of FIG. 9, in order to attach the board holder 14 to the circuit board 13, firstly insert the latch bar 144 into the holder latch groove 133 of the circuit board. In this state, rotate the board holder 14 so that the front end and top end of the circuit board 13 are completely inserted into the interior of the board holder 14.

By rotating the board holder 14 until the third surface 1413 of the board holder 14 and the front end of the circuit board 13 are parallel to each other, the circuit board 13 is completely inserted into the interior of the board holder 14. In this state, the fastening member S, such as a screw, is inserted into the fastening boss 143 of the board holder 14.

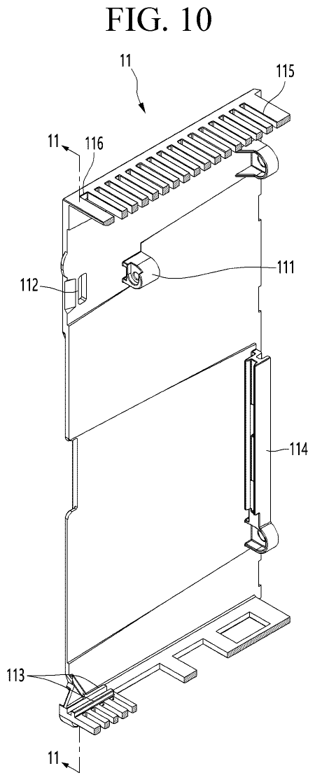

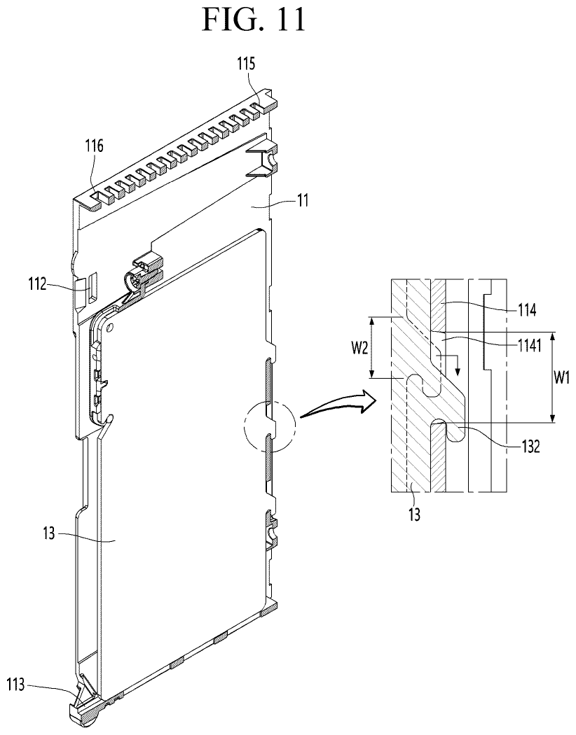

FIG. 10 is a sectional perspective view of the housing cut along 4-4 in FIG. 3 with the circuit board separated, and FIG. 11 is a sectional perspective view of the housing cut along 11-11 in FIG. 10 with the circuit board attached to the housing.

Referring to FIGS. 10 and 11, the front of the housing 11 is open and may be selectively shielded by the cover 12. The rear of the housing 11 may also be open.

When multiple control boxes are arranged in a modular configuration, multiple control boxes are arranged in the lateral direction of the housing 11. Then, the front surfaces of the multiple control boxes do not overlap or interfere with adjacent control boxes. Therefore, there is an advantage that, to replace the circuit board inside a specific control box, only the cover 12 forming the front surface of the specific control box needs to be disassembled, without separating adjacent control boxes.

In detail, multiple heat dissipation slits (or heat dissipation holes) 115 may be formed on the upper and lower surfaces of the housing 11, and a heat dissipation fan not shown may be arranged on a lower side of the housing 11 to allow air to pass through the interior of the housing 11 for heat exchange.

Additionally, an upper hook hole 116 may be formed on the upper surface of the housing 11, and the multiple heat dissipation slits 115 may be arranged behind the upper hook hole 116.

The circuit board 13 may be arranged on one side of either the left side or the right side of the interior of the housing 11. A protrusion may be formed on one side of the interior of the housing 11, and the protrusion may be defined as a holder flange 111. The fastening boss 143 of the board holder 14 is seated on the holder flange 111. Furthermore, a fastening member S that passes through the fastening boss 143 is inserted into the holder flange 111, allowing the second portion of the board holder 14 to be fixed to the housing 11. The second portion may be defined as the other end of the board holder 14.

Side hook holes 112 are formed on both sides of the housing 11, and a pair of side lockers 24 constituting the cover lock module 20 described above are detachably connected to the side hook holes 112.

A pair of board support ribs 113 may be extended from the bottom surface of the housing 11. The pair of board support ribs 113 may extend a predetermined length rearward from the front end of the housing 11. The lower portion of the circuit board 13 is inserted into the space formed between the pair of board support ribs 113, thereby preventing the circuit board 13 from shaking in the width direction of the housing 11 due to external forces.

A board support bracket 114 is formed on one side of the housing 11 adjacent to the rear surface of the housing 11. One or more insertion holes 1141 are formed inside the board support bracket 114. The insertion holes 1141 may be formed in a number corresponding to the number of insertion projections 132 formed on the circuit board 13.

The vertical width W1 of the insertion hole 1141 is formed larger than the maximum vertical width W2 of the insertion protrusion 132, allowing the insertion protrusion 132 to be inserted into the insertion hole 1141 without interference.

In detail, in order for a worker to install the circuit board 13 inside the housing 11, firstly the worker pushes the circuit board 13 horizontally into the housing 11 until the insertion protrusion 132 is fully inserted into the insertion hole 1141. Once the insertion protrusion 132 is inserted into the insertion hole 1141, the worker lowers the circuit board 13 to the bottom of the housing as shown in the drawing. Then, the bent end of the insertion protrusion 132 will engage with the board support bracket 114. At the same time, the lower end of the circuit board 13 is inserted between the pair of board support ribs 113. Alternatively, when a portion of the insertion protrusion 132 is inserted into the insertion hole 1141, the action of pushing the circuit board 13 backward and the action of lowering the circuit board 13 downward can be performed simultaneously, so that the insertion protrusion 132 is inserted into the insertion hole 1141 along a diagonal line.

In this state, by connecting one end of the board holder 14 to the circuit board 13 and fixing the other end to the holder flange 111, the circuit board 13 is securely fixed inside the housing 11 without any shaking.

To replace the circuit board 13, the assembly process is reversed. That is, the cover 12 may be rotated to be open from the housing 11 or separated from the housing 11, and then a tool is inserted through the open front of the housing 11 to separate the fastening member S that fastens the board holder 14 and the housing 11. Then, the circuit board 13 may be pulled forward with the board holder 14 connected to be removed from the housing 11.

Alternatively, it is also possible to separate the fastening member S so that the second part of the board holder 14 is separated from the housing 11, and then separate the first part of the board holder 14 from the circuit board 13, followed by separating the circuit board 13 from the housing 11.

In this process, there is no need to disassemble or remove other control boxes 10 arranged on the side of the control box 10, resulting in significantly improved work efficiency.

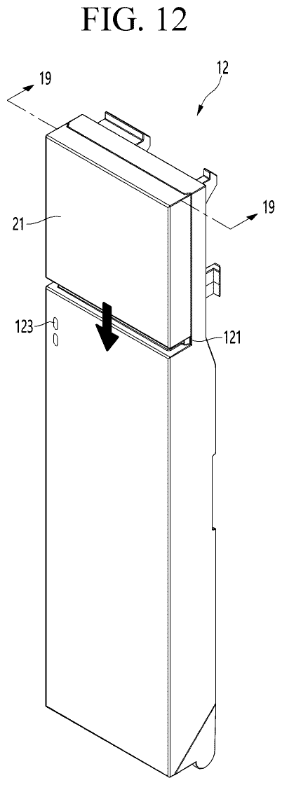

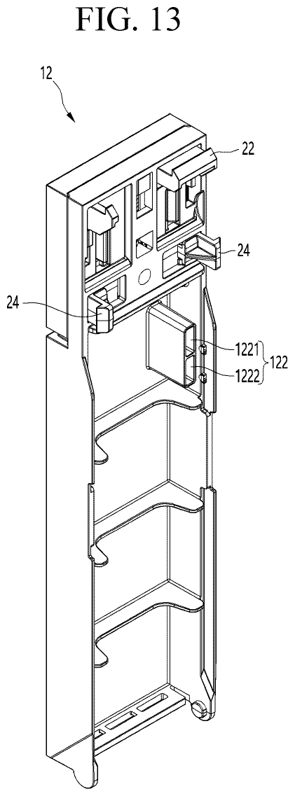

FIG. 12 is a front perspective view of the cover that is coupled to the housing, and FIG. 13 is a rear perspective view of the cover.

Referring to FIGS. 12 and 13, as described above, in a state where the cover 12 is secured to the front of the housing 11, when the slider 21 is lowered in the direction of the arrow, the locking end of the upper locker 22 descends, and the locking ends of the pair of side lockers 24 move horizontally toward the center of the cover 12, allowing the cover 12 to be released from the housing 11. When the force applied to the slider 21 is removed in this state, the slider 21 rises back to its original position due to the restoring force of the spring 23, and the upper locker 22 and side lockers 24 engage with the locking holes described later formed in the housing 11 to lock in place.

Meanwhile, a light guide 122 is formed on a back side of the cover 12 to extend for a predetermined length. The light guide 122 is formed at a position corresponding to the front of the light source 15, and the front surface of the light guide 122 is defined as the hidden display 123.

Inside the light guide 122, a number of light passages corresponding to the number of light sources 15 are formed. In this embodiment, the light passages are limited to the first light passage 1221 and the second light passage 1222.

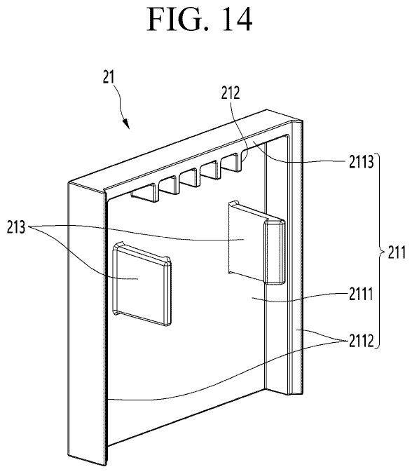

FIG. 14 is a rear perspective view of the slider constituting the cover lock module according to an embodiment of the present invention.

Referring to FIG. 14, the slider 21 constituting the cover lock module 20 according to an embodiment of the present invention may include a slider body 211, a pressing rib 212, and a slider hook 213.

In detail, the slider body 211 includes a front portion 2111, a pair of side portions 2112 extending rearward from the left and right edges of the front portion 2111, an upper surface portion 2113 extending rearward from the upper end of the front portion 2111, and the lower surface portion of the slider body 211 may be provided in an open form.

Additionally, the pressing rib 212 may be provided in a form extending downward from the lower surface of the upper surface 2113 for a predetermined length. The pressing rib 212 may be provided in a form where multiple vertical ribs are spaced apart in a horizontal direction, as shown in the figure, or in a form of a single U-shaped rib.

Furthermore, the slider hook 213 extends rearward from the rear surface of the front surface 2111. Specifically, the slider hook 213 may include a pair of hooks that respectively protrude rearward from positions adjacent to the left and right edges of the rear surface of the front surface 2111.

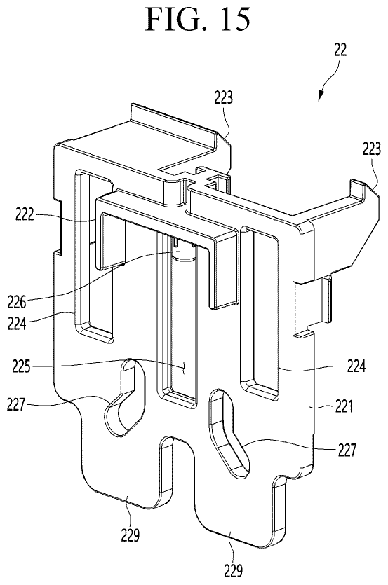

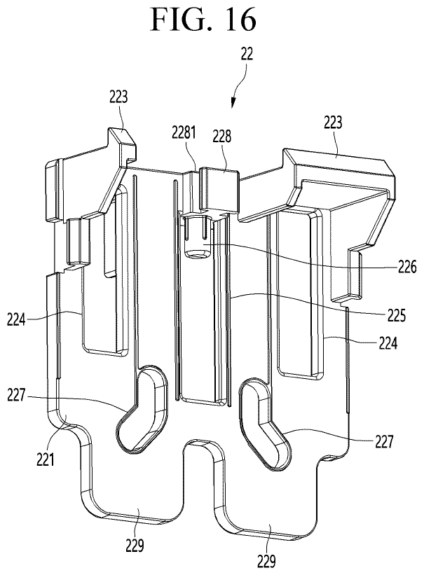

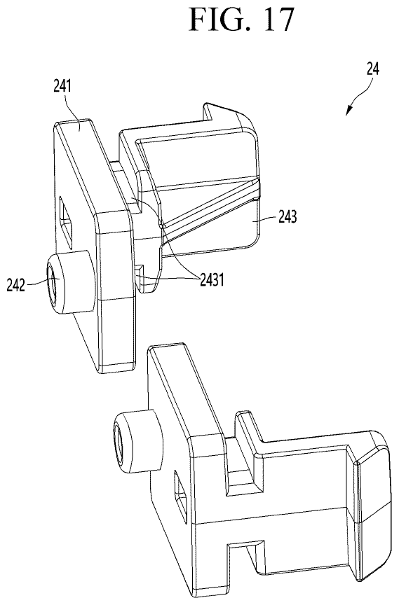

FIG. 15 is a front perspective view of the upper locker constituting the cover lock module according to an embodiment of the present invention, and FIG. 16 is a rear perspective view of the upper locker.

Referring to FIGS. 15 and 16, the upper locker 22 constituting the cover lock module 20 according to an embodiment of the present invention may include an upper locker body 221, a front rib 222, an upper hook 223, an upper support boss 226, a lifting guide 228, and an insertion rib 229.

In detail, the upper locker body 221 may be formed as a square plate so that it can be accommodated inside the slider 21.

The front rib 222 protrudes forward from the front of the upper locker body 221 and may be formed at a point spaced downward from the top of the upper locker body 221. The front rib 222 may extend horizontally for a predetermined length or, as shown in the figure, may extend further downward from both ends of the horizontally extended portion.

The upper surface of the front rib 222 is pressed by the pressing rib 212 of the slider 21, thereby functioning to lower the upper locker 22 as one piece with the slider 21.

The upper hook 223 extends rearward from the upper end of the upper locker body 221 and may be provided in one or more pieces. In this embodiment, a pair of upper hooks 223 extend rearward from both ends of the upper locker body 221 and engage the upper hook holes 116 formed on the upper surface of the housing 11. The pair of upper hooks 223 may be of the same size or may be designed with different widths, as shown in the figure.

The insertion rib 229 extends downward from the lower end of the upper locker body 221 for a predetermined length. The insertion rib 229 may be formed as a single rib extending downward, or as multiple ribs, such as a pair of ribs extending downward, as shown in the figure.

Meanwhile, a spring hole 225 may be formed at the center of the upper locker body 221. Specifically, the spring hole 225 may extend downward from a point spaced apart from the upper end of the upper locker body 221 by a predetermined length. For example, the upper end of the spring hole 225 may be located at the same height as the lower surface of the front rib 222, but this is not necessarily limited to this.

Additionally, a pair of slider hook guide holes 224 may be formed in the upper locker body 221. The pair of slider hook guide holes 224 extends downward from the point where it is offset downward from the top of the upper locker body 221. The pair of slider hook guide holes 224 may be formed at points offset to the left and right of the spring hole 225, respectively. Alternatively, the pair of slider hook guide holes 224 may be described as being formed at points adjacent to the left and right edges of the upper locker body 221.

Additionally, the upper locker body 221 may have a pair of guide protrusion holes 227 formed therein. In detail, the pair of guide protrusion holes 227 may be formed on the left and right sides of the spring hole 225, respectively, at points adjacent to the lower end of the spring hole 225. Furthermore, the pair of guide protrusion holes 227 may be inclined and extended in a direction in which they become closer to each other as they extend upwardly. Alternatively, the pair of guide protrusion holes 227 may be described as being inclined and extended in a direction in which they become closer to the spring hole 225 as they extend upwardly. Depending on the design conditions, each of the pair of guide protrusion holes 227 may be formed in a shape that includes a portion (second hole) extending upwardly from the top of the inclined portion (first hole), as shown in the figure, in addition to the inclined extension shape.

The lifting guide 228 protrudes rearward from the rear surface of the upper locker body 221, specifically at the point between the upper end of the upper locker body 221 and the upper end of the spring hole 225. Guide grooves 2281 are formed on both sides of the lifting guide 228. The guide grooves 2281 may be formed along the length from the top to the bottom of the lifting guide 228.

The upper support boss 226 is a portion where the upper end of the spring 23 is hooked, and extends downward from the bottom surface of the lifting guide 228 for a predetermined length and is inserted into the interior of the spring 23. The upper support boss 226 is inserted into the upper end of the spring 23, preventing the upper end of the spring 23 from detaching from the upper locker 22. Furthermore, the formation of the spring hole 225 prevents interference between the spring 23 and the upper locker body 221.

FIG. 17 is a perspective view of the side locker constituting the cover lock module according to an embodiment of the present invention.

Referring to FIG. 17, the cover lock module 20 according to an embodiment of the present invention includes a pair of side lockers 24.

In detail, the pair of side lockers 24 includes a left side locker and a right side locker. Each of the pair of side lockers 24 includes a side locker body 241, a guide protrusion 242, and a side hook 243. The guide protrusion 242 protrudes a predetermined length from the front of the side locker body 241 and is formed at a point adjacent to either the left edge or the right edge of the side locker body 241. For example, the guide protrusion 242 of the left side locker may be formed on the right edge of the side locker body 241, and the guide protrusion 242 of the right side locker may be formed on the left edge of the side locker body 241. The pair of guide projections 242 are each inserted into the pair of guide projection holes 227 formed in the upper locker 22, and move in a left and right direction along the guide projection holes 227 when the upper locker 22 moves up and down.

The side hooks 243 extend from the rear surface of the side locker body 241. The side hooks 243 of the left side locker and the side hooks 243 of the right side locker are formed symmetrically, with the protrusions extending in opposite directions. Therefore, as the slider 21 moves in the vertical direction, the pair of side lockers 24 move horizontally toward each other or away from each other, inserted into or separated from the side hook holes 112 formed on both sides of the housing 11.

The side hooks 243 have a pair of guide grooves 2431 formed therein, and the pair of guide grooves 2431 may be formed on the upper surface and lower surface of the side hooks 243, respectively.

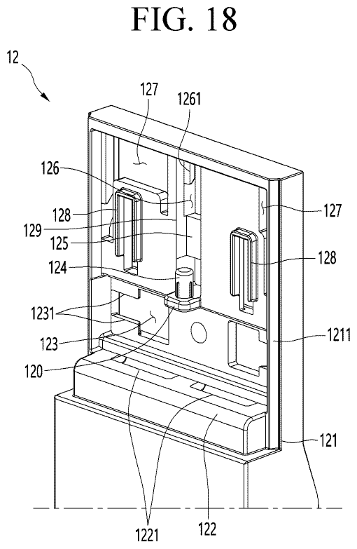

FIG. 18 is an enlarged view showing the step portion of the cover to which the cover lock module according to an embodiment of the present invention is attached.

Referring to FIG. 18, a step portion 121 is formed on the upper front portion of the cover 12, and the step portion 121 is covered by the slider 21.

In detail, a slider support ridge 122 protrudes from the lower end of the step portion 121, and an insertion rib through hole 1221 is formed on the upper surface of the slider support ridge 122. The insertion rib 229 extending from the lower end of the upper locker 22 is inserted into the insertion rib through hole 1221. Furthermore, the front surface of the slider support ridge 122 supports the front portion 2111 of the slider 21. Additionally, side support ridges 1211 are formed on both side edges of the step portion 121 to support the side portions 2112 of the slider 21. Specifically, the side portion 2112 of the slider 21 moves up and down while being in close contact with the side support ridges 1211, thereby preventing lateral shaking during movement. Furthermore, the lower end of the rear surface of the front portion 2111 of the slider 21 moves in a state closely adhered to the front of the slider support ridge 122, thereby preventing the slider from shaking in the front-rear direction during movement.

Meanwhile, the inner space of the step portion 121 defined by the pair of side support ridges 1211, the upper surface of the slider support ridge 122, and the upper surface of the cover 12 can be defined as the cover lock module mounting portion.

The cover lock module mounting portion includes a side locker through hole 123, an lifting guide through hole 126, an upper hook through hole 127, a slider hook insertion hole 128, and a spring receiving hole 129.

In detail, the spring receiving hole 129 extends vertically for a predetermined length from the approximate central portion of the cover lock module mounting portion. Specifically, the spring receiving hole 219 extends downward from the upper end of the cover lock module mounting portion (or the upper end of the step portion) for a predetermined length and may extend to a point spaced upward from the upper surface of the slider support ridge 122. The spring receiving hole 129 receives the spring 23.

A spring support rib 125 may be formed at any point between the upper and lower ends of the spring receiving hole 219. The spring support rib 125 functions to support the spring 23 accommodated in the spring receiving hole 219 so that it does not bend during the compression process of the spring 23.

The opening formed on the upper side of the spring support rib 125 is defined as the lifting guide through hole 126, into which the lifting guide 228 protruding from the rear surface of the upper locker 22 is inserted. Guide ribs 1261 extend from the left and right edges of the lifting guide through hole 126, and the pair of guide ribs 1261 are inserted into a pair of guide grooves 2281 recessed into both sides of the lifting guide 228. This structure helps the upper locker 22 move up and down smoothly by having the guide ribs 1261 support the lifting guide 228 when the upper locker 22 moves up and down.

The lower end of the spring receiving hole 129 has an extension end 120 protruding horizontally forward, and the upper surface of the extension end 120 has a lower support boss 124 extending upward by a predetermined length. The lower support boss 124 is inserted into the lower end of the spring 23 to support the spring 23.

In detail, when the lifting guide 228 is inserted into the lifting guide through hole 126, the lower support boss 124 is located right below the upper support boss 226. As a result, the center axis of the spring 23 becomes coaxial with the center axes of the upper support boss 226 and lower support boss 124.

Meanwhile, the upper hook through holes 127 are formed on the left and right sides of the spring receiving hole 129, respectively, and the upper hook 223 of the upper locker 22 passes through the upper hook through holes 127. The upper hook 223 passes through the upper hook through hole 127 and engages with the upper hook hole 116 formed on the upper surface of the housing 11.

The slider hook insertion hole 128 is formed on the left and right sides of the spring receiving hole 129 and extends a predetermined length in the vertical direction. Furthermore, the pair of slider hooks 213 extending from the back surface of the slider 21 pass through the pair of slider hook insertion holes 128 and engage with the rear surface of the cover lock module mounting portion. With the slider hooks 213 hooked onto the rear side of the cover lock module mounting portion, the slider 21 can move stably in the vertical direction.

The side locker through holes 123 are formed below the spring receiving holes 129 and are formed on the left and right sides of the cover lock module mounting portion, respectively. The pair of side lockers 24 are inserted into the pair of side locker through holes 123, respectively.

Guide ribs 1231 are formed on the upper edge and lower edge of each of the pair of side locker through holes 123. The pair of guide ribs 1231 are inserted into the guide grooves 2431 formed in the side lockers 24, preventing the side lockers 24 from disengaging from the side locker through holes 123. Additionally, the guide ribs 1231 are inserted into the guide grooves 2431 to guide the horizontal movement of the side locker 24.

The horizontal length of the guide rib 1231 is formed shorter than the horizontal length of the side locker through hole 123. Therefore, after the side hook 243 of the side locker 24 is inserted into the space where the guide rib 1231 is not formed, when the guide protrusion 242 of the side locker 24 is inserted into the guide protrusion hole 227 of the upper locker 22, the guide rib 1231 is inserted into the guide groove 2431 of the side locker 24. Furthermore, when the guide protrusion 242 moves left and right along the guide protrusion hole 227, the guide rib 1231 moves relative to the guide groove 2431.

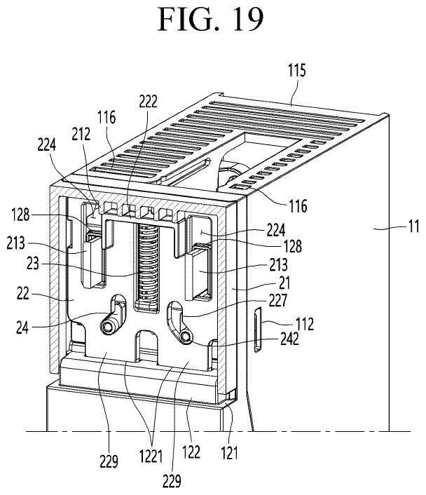

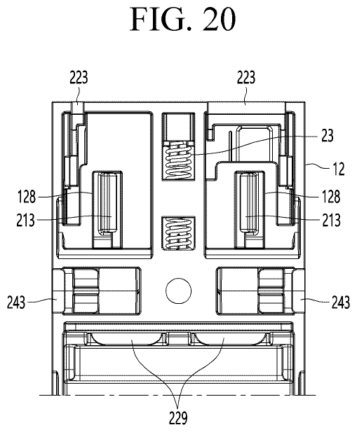

FIG. 19 is a cross-sectional view of the control box along the 19-19 section of FIG. 12, showing the appearance before the slider descends, and FIG. 20 is a rear view of the cover in the state shown in FIG. 19.

Referring to FIGS. 19 and 20, before the slider 21 descends, the upper hook 223 remains engaged in the upper hook hole 116, and the side hook 243 remains engaged in the side hook hole 112.

In this state, the guide protrusion 242 of the side locker 24 remains hooked in the lower part of the guide protrusion hole 227. Additionally, the spring 23 remains in its original state before compression.

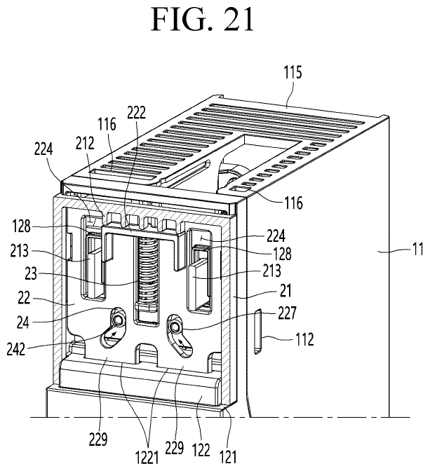

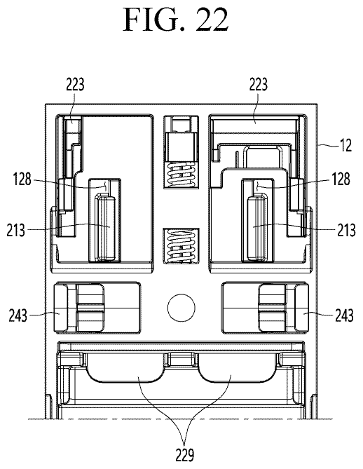

FIG. 21 is a cross-sectional view of the control box along the 19-19 section of FIG. 12, showing the slider in its fully lowered state, and FIG. 22 is a rear view of the cover in the state shown in FIG. 21.

Referring to FIGS. 21 and 22, when the slider 21 descends in the direction of the arrow in FIG. 12, the lower end of the slider 21 engages with the lower end of the step portion 121.

In this process, the pressing rib 212 of the slider 21 presses the front rib 222 of the upper locker 22, causing the upper locker 22 to descend. As the upper locker 22 descends, the upper hook 223 is separated from the upper hook hole 116, and the spring 23 is compressed.

Furthermore, as the upper locker 22 descends, the guide protrusion hole 227 also descends, and as the guide protrusion hole 227 descends, the guide protrusions 242 of the side locker 24 move horizontally toward each other along the guide protrusion holes 227 that are inclined at an angle. As a result, the side hook 243 is separated from the side hook hole 112, causing the cover 12 to become separable from the housing 11, i.e., unlocked.

In this state, when the force applied to the slider 21 is removed, the slider 21 and the upper locker 22 rise to their original positions due to the elastic force of the spring 23, and finally, the upper hook 223 engages with the upper hook hole 116, the side hook 243 engages with the side hook hole 112, returning the cover 12 to the housing 11 in a locked state.

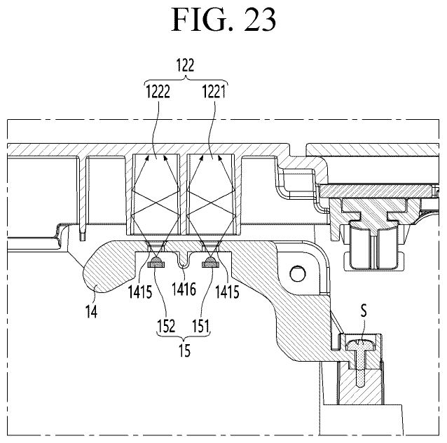

FIG. 23 is a diagram showing the path of light emitted from the light source.

Referring to FIG. 23, light of different colors emitted from the first light source 151 and the second light source 152 sequentially pass through the light passage hole 1415 of the board holder 14 and the light guide 12 and are projected onto the rear surface of the hidden display 123. The light irradiated onto the rear surface of the hidden display 123 then passes through the hidden display 123 and is perceived by the user's eyes.

Here, the light emitted from the first light source 151 and the light emitted from the second light source 152 do not interfere with each other and pass through the light transmission holes 1415 respectively, due to the blocking wall 1416 formed between the adjacent light transmission holes 1415.

Furthermore, the light-transmitting holes 1415 are formed in such a way that their width gradually expands toward the light guide 122 from the light source 15, enabling the light emitted from the light source 15 to be diffusely guided into the interior of the light guide 122.

Furthermore, the lower end of the light guide 12 is spaced apart from the upper surface of the board holder 14, so that even when the cover 12 is attached to the front of the housing 11, the light guide 12 and the upper surface of the board holder 14 do not interfere with each other.

What is claimed is:

1. A control box, comprising:
a housing;
a circuit board disposed inside the housing; and
a board holder including a first part connected to the circuit board and a second part connected to the housing;
a fastening member for securing the board holder to the housing,
wherein at least one of planes passing through the first part and the second part is configured to be parallel to a component mounting surface of the circuit board.

2. The control box of claim 1, wherein a front end of the circuit board has a holder engagement groove into which the first part engages,
and wherein the first part has an engagement bar that engages with the holder engagement groove.

3. The control box of claim 1, wherein a fastening boss is formed on the second part,
a holder flange is formed on an inner side of the housing to accommodate the fastening boss,
and wherein the fastening boss is fixed to the holder flange by the fastening member.

4. The control box of claim 3, wherein the fastening member is sequentially inserted into the fastening boss and the holder flange in a direction from a front to a rear of the housing.

5. The control box of claim 1, wherein the board holder includes a cable holder protruding for cable support.

6. The control box of claim 1, wherein the board holder includes a flexible latch portion formed thereon,
and wherein the circuit board includes a protrusion insertion portion into which the latch portion is inserted.

7. The control box of claim 6, wherein the latch portion includes:
a latch body formed by cutting a portion of the circuit board; and
a latch protrusion protruding from an end of the latch body,
wherein the latch protrusion is inserted into the protrusion insertion hole.

8. The control box of claim 7, wherein an end of the latch protrusion is formed at an oblique angle, such that during the process of attaching the board holder to the circuit board, the latch body gradually bends as it slides along a surface of the circuit board,
and when the latch protrusion is inserted into the protrusion insertion hole, the latch body is restored to its original position by elastic force.

9. The control box of claim 1, wherein one or more insertion protrusions are formed on a rear end of the circuit board,
and wherein the housing includes a board support bracket that supports the one or more insertion protrusions.

10. The control box of claim 9, wherein one or more insertion holes are formed inside the board support bracket in which the one or more insertion protrusions are inserted.

11. The control box of claim 10, wherein, after the circuit board is inserted into the housing until the one or more insertion protrusions are inserted into the one or more insertion holes, the one or more insertion protrusions are supported by being engaged with the board support bracket by a descending motion of the circuit board.

12. The control box of claim 11, wherein the bottom surface of the housing is formed with a pair of support ribs that support a lower end of the circuit board,
and when the one or more insertion protrusions engage with the circuit board support bracket, the lower end of the circuit board is inserted into a space formed between the pair of support ribs.

13. The control box of claim 1, wherein one or more light-transmitting holes are formed inside the board holder,
and wherein a partition wall is formed between the multiple light-transmitting holes.

14. The control box of claim 13, wherein one or more light sources are mounted on the circuit board.

15. The control box of claim 14, wherein, in a state where the board holder is coupled to the circuit board, light emitted from the one or more light sources is directed toward the one or more light-transmitting holes.

16. The control box of claim 15, wherein further comprising a cover that opens or closes an opened front surface of the housing,
wherein a light guide protrudes from a rear of the cover,
and wherein one or more light passages are formed inside the light guide.

17. The control box of claim 1, wherein the board holder is bent to cover a corner where the front and top edges of the circuit board meet.

18. The control box of claim 1, wherein the direction in which the circuit board is inserted into the housing and the direction in which the fastening member is inserted into the housing are the same.

19. A control box, comprising:
a housing;
a circuit board located inside the housing;
a board holder connected to the housing and the circuit board; and
a fastening member for fixing the board holder to the housing,
wherein at least a portion of an edge of the circuit board is inserted into the board holder, so that both sides of the circuit board are supported by the board holder.

20. A control box, comprising:
a housing;
a circuit board located inside the housing;
a board holder connected to the housing and the circuit board; and
a fastening member for securing the board holder to the housing,
wherein the board holder is secured to a protruding portion within the housing by the fastening member, thereby keeping the circuit board spaced apart from the inner wall of the housing.
